(19) United States
(12) Patent Application Publication
(10) Pub. No.: US 2012/0308739 A1
(43) Pub. Date: Dec. 6, 2012

(54) METHODS FOR DEPOSITION OF ALKALINE EARTH METAL FLUORIDE FILMS

(75) Inventors: Clément LANSALOT-MATRAS, Seoul (KR); Julien Gatineau, Tsuchiura (JP)

(73) Assignee: L'Air Liquide Societe Anonyme pour I'Etude et I'Exploitation des Procedes Georges Claude, Paris (FR)

(21) Appl. No.: 13/474,353

(22) Filed: May 17, 2012

Related U.S. Application Data
(60) Provisional application No. 61/491,309, filed on May 30, 2011.

(51) Int. Cl. C23C 16/08; C23C 16/50

(52) U.S. Cl. 427/569; 427/255.391; 427/255.39

(57) ABSTRACT

Disclosed are thermal and/or plasma-enhanced CVD, ALD, and/or pulse CVD processes to deposit alkaline earth metal fluoride-based films, such as MgF₂, at temperatures ranging from about 25° C. to about 300° C., preferably from about 50° C. to about 250° C., and more preferably from about 100° C. to about 200° C.

### CROSS-REFERENCE TO RELATED APPLICATIONS

This application claims the benefit under 35 U.S.C. §119(e) to provisional application No. 61/491,309, filed May 30, 2011, the entire contents of which are incorporated herein by reference.

### TECHNICAL FIELD

The disclosed methods relate to thermal and/or plasma-enhanced CVD, ALD, and/or pulse CVD processes to deposit alkaline earth metal fluoride-based films.

### BACKGROUND

Anti-refractive layers (ARL) or coatings (ARC) are important in many manufacturing processes, such as optical coatings. These coatings have been introduced to the Complementary Metal-Oxide Semiconductor (CMOS) image sensor manufacturing process. The CMOS Image Sensor (CIS) is an alternative to the Coupled Charge Detector (CCD) for light sensor applications. Anti-reflective coatings are deposited on the top of the image sensor, onto the micro-lens. The coating protects the micro-lens and increases the CIS sensitivity. The coating layer must have a refractive index lower than that of the micro-lens, which may be made of SiO₂. In that situation, the ARC requires a refractive index <1.46.

Some materials with low dielectric constant (low-k) used in the manufacturing process of many electronic devices also exhibit a low refractive index (<1.35) that may allow them to be used as coatings. However, the use of a UV curing post-process is sometimes required to improve the film characteristics and this step may generate damages in the CIS sub-layers.

MgF₂ has a RI of 1.35 (at 400 nm) and does not need a UV curing step. Mg-containing films have been deposited using ALD (see, e.g., US Pat. App. Pub. No. 2008/210973 to Chen et al.). However, in that application, the Mg served as a doping agent in a zinc oxide film. The reference does not disclose whether the process would produce a satisfactory alkaline earth metal fluoride film. Mg(tfac)₂.2H₂O.2diglyme has been used as a single source precursor for the growth of MgF₂ films at high temperature (300-350° C.) (Maria E. Fragala et al. Chem. Mater., Vol. 21, No. 10, 2009 2063). Additionally, a plasma source may be used to improve the decomposition of the single source Mg(hfac)₂ in order to prepare MgF₂ films in CVD mode (U.S. Pat. No. 4,718,929). In another reference, MgF₂ films have been prepared using Mg(acac)₂ mixed with trifluoroacetic acid at high temperature (900-1200° F.) in CVD mode (U.S. Pat. No. 5,165,960).

Metal fluorinated precursors may also be used as fluorine sources for the deposition of MgF₂ films. For instance, the use of TiF₄ or TaF₅ as fluorine source in association with Mg(tmhd)₂ as magnesium source has been described in Atomic Layer Deposition (ALD) mode from 250° C. (Pilvi Tero—Applied Optics 47, 13, 2008; Pilvi Tero—J of Mater. Chem. 2007 17, 5077-5083; Pilvi Tero—Chem Mater 2008 20, 5023-5038).

TiF₄, TaF₅, NbF₅, XeF₂ or SbF₅ are commercially available metal fluorinated precursor compounds. Other metal fluorinated precursors may be suitable for use in the deposition of alkaline earth metal fluoride films.

One issue encountered in the deposition of MgF₂ films is incorporation of impurities, such as other metals or oxygen. MgO has a refractive index of 1.7, resulting in too high a refractive index for the ARL application.

A need remains for deposition methods of suitable alkaline earth metal fluoride films at temperatures below approximately 300° C., preferably below 250° C., and more preferably below 200° C.

### Notation and Nomenclature

Certain abbreviations, symbols, and terms are used throughout the following description and claims and include:

The standard abbreviations of the elements from the periodic table of elements are used herein. It should be understood that elements may be referred to by these abbreviations (e.g., Si refers to silicon, Zr refers to zirconium, Pd refers to palladium, Co refers to cobalt, etc).

As used herein, the term “independently” when used in the context of describing L, Y, or R groups should be understood to denote that the subject L, Y, or R group is not only independently selected relative to other L, Y, or R groups bearing the same or different subscripts or superscripts, but is also independently selected relative to any additional species of that same L, Y, or R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used herein, the term “alkyl group” refers to saturated functional groups containing exclusively carbon and hydrogen atoms, which may be linear, branched, or cyclic. Examples of linear alkyl groups include without limitation, methyl groups, ethyl groups, propyl groups, butyl groups, etc. Examples of branched alkyl groups include without limitation, t-butyl. Examples of cyclic alkyl groups include without limitation, cyclopropyl groups, cyclopentyl groups, cyclohexyl groups, etc. As used herein, the abbreviation “Me” refers to a methyl group; the abbreviation “Et” refers to an ethyl group; the abbreviation “Pr” refers to a propyl group; the abbreviation “iPr” refers to an isopropyl group; the abbreviation “Bu” refers to butyl (n-butyl); the abbreviation “tBu” refers to tert-butyl; and the abbreviation “sBu” refers to sec-butyl.

As used herein, the term “aryl group” means a ligand derived from an aromatic molecule, such as phenyl, benzyl, tolyl, or o-xylol; the abbreviation “tmhd” refers to 2,2,6,6-tetramethyl-3,5-heptadionato; the abbreviation “od” refers to 2,4-octadionato; the abbreviation “mhd” refers to 2-methyl-3,5-hexadinonato; the abbreviation “tmod” refers to 2,2,6,6-tetramethyl-3,5-octanedionato; the abbreviation “ibpm” refers to 2,2,6-trimethyl-3-5-heptadionato; the abbreviation “hfac” refers to hexafluoroacetylacetonato; the abbreviation “tfac” refers to trifluoroacetylacetonato; and the abbreviation “dkti” refers to diketimine.

For a better understanding of the following ligands, the generic structures are represented below. The abbreviation “acac” refers to acetylacetonate, depicted as A below; the abbreviation “emk” refers to enaminoketones, depicted as B below; the abbreviation “dab” refers to diazabutadiene, depicted as D below; the abbreviation “amd” refers to amidinate, depicted as E below; the abbreviation “fmd” refers to formamidinate, depicted as F below; the abbreviation “gnd” refers to guanidinate, depicted as G below; the abbreviation “Cp” refers to cyclopentadienyl, depicted as I below; the abbreviation “Cp*” refers to pentamethylcyclopentadienyl, in which R is Me in I below; the abbreviation “op” refers to (open)pentadienyl, depicted as J below; the abbreviation “chd” refers to cyclohexadienyl, depicted as K below; the abbreviation “hd” refers to hexadienyl, depicted as L below; the abbreviation “cod” refers to cyclooctadiene, depicted as O below. Also shown are J3-diketiminate as C, iminomethylpyrrolyl as H, cycloheptadienyl as M, heptadienyl as N, and octadienyl as P. The ligands shown are generic structures that can be further substituted by substitution groups, wherein each R is independently selected from: H; a C1-C6 linear, branched, or cyclic alkyl or aryl group; an amino substituent such as NR1R2 or NR1R2R3, where R1, R2 and R3 are independently selected from H, and a C1-C6 linear, branched, or cyclic alkyl or aryl group; and an alkoxy substituent such as OR, or OR1R2 where R1 and R2 are independently selected from H, and a C1-C6 linear, branched, or cyclic alkyl or aryl group.

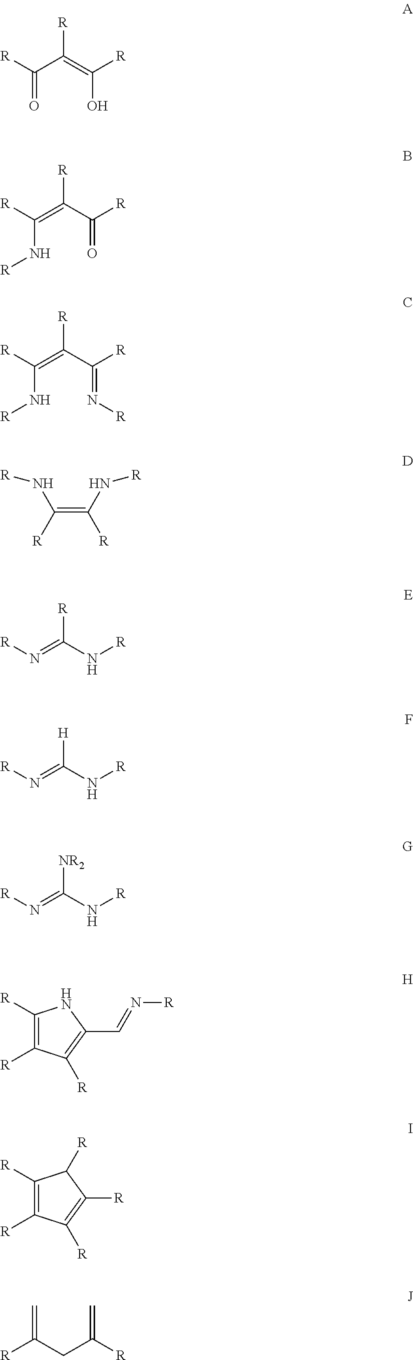

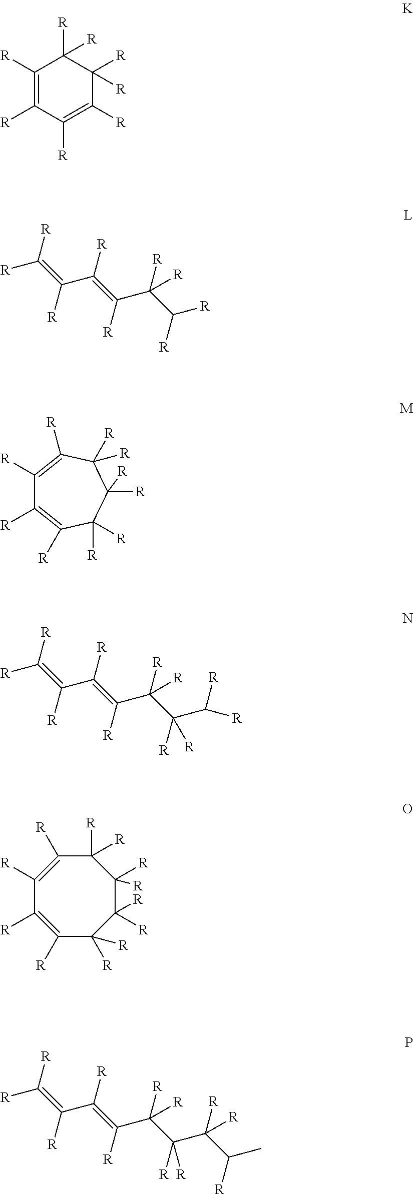

### SUMMARY

Disclosed are methods for depositing an alkaline earth metal fluoride film onto one or more substrates. The vapor of at least one alkaline earth metal precursor is introduced into a reaction chamber containing one or more substrates. The vapor of at least one fluorinated metal precursor into the reaction chamber. The alkaline earth metal precursor and the fluorinated metal precursor react to deposit the alkaline earth metal fluoride film onto the one or more substrates. The alkaline earth metal precursor having the general formula:

ML¹ₒₓY¹ₚ

wherein:
M is magnesium (Mg), calcium (Ca), strontium (Sr), or barium (Ba);
each L¹ is independently selected from the group consisting of acetylacetonate, enaminoketonate, β-diketiminate, diazabutadienyl, amidinate, formamidinate, guanidinate, iminomethylpyrrolyl, cyclopentadienyl, pentadienyl, cyclohexadienyl, hexadienyl, cycloheptadienyl, heptadienyl, cyclooctadienyl, and octadienyl, each of which may be substituted by C1-C4 linear, branched, or cyclic alkyl group; C1-C4 linear, branched, or cyclic mono, bis, or tris-alkylsilyl group; C1-C4 linear, branched, or cyclic alkylamino group; or a C1-C4 linear, branched, or cyclic fluoroalkyl group;
each Y¹ is a Lewis base independently selected from monoglyme, polyglyme, pyridine, THF, diethylether, or H₂O;
ox is an integer representing an oxidation state of the alkaline earth metal M; and
p is a number selected between 0 and 4.

The fluorinated metal precursor having the general formula:

NFₒₓₓ₋ₓL²_{oxx-y}Y²ₚ

wherein:
N is Titanium (Ti), Tantalum (Ta), Niobium (Nb), Xenon (Xe), Antimony (Sb), or Hafnium (Hf);
each L² is independently selected from the group consisting of acetylacetonate, enaminoketonate, β-diketiminate, diazabutadienyl, amidinate, formamidinate, guanidinate, iminomethylpyrrolyl, cyclopentadienyl, pentadienyl, cyclohexadienyl, hexadienyl, cycloheptadienyl, heptadienyl, cyclooctadienyl, and octadienyl, each of which may be substituted by C1-C4 linear, branched, or cyclic alkyl group; C1-C4 linear, branched, or cyclic mono, bis, or tris-alkylsilyl group; C1-C4 linear, branched, or cyclic alkylamino group; or a C1-C4 linear, branched, or cyclic fluoroalkyl group;
each Y² is a Lewis base independently selected from monoglyme, polyglyme, pyridine, THF, dimethylether, or diethyl ether;
oxx is an integer representing the oxidation state of the metal N;
x is an integer selected between 1 and oxx;
y is an integer selected between 0 and oxx;
the sum of x and y is equal to oxx;
p is a number selected between 0 and 4; and
the alkaline earth metal precursor is not Mg(tmhd)₂ when the fluorinated metal precursor is TiF₄ or TaF₅.

The disclosed methods may include on or more of the following aspects:
the alkaline earth metal precursor being selected from the group consisting of MgCp₂, Mg(MeCp)₂, Mg(Cp*)₂, Mg(EtCp)₂, Mg(nPrCp)₂, Mg(iPrCp)₂, Mg(nBuCp)₂, Mg(isoBuCp)₂, Mg(secBuCp)₂, Mg(op)₂, Mg(acac)₂, Mg(acac)₂.2H₂O, Mg(acac)₂.tetraglyme Mg(acac)₂.2H₂O.2diglyme, Mg(tmhd)₂, Mg(tmhd)₂.2H₂O, Mg(tmhd)₂.tetraglyme Mg(tmhd)₂.2H₂O.2diglyme, Mg(od)₂, Mg(tfac)₂, Mg(tfac)₂.2H₂O, Mg(tfac)₂.tetraglyme, Mg(tfac)₂.2H₂O.2diglyme, Mg(hfac)₂, Mg(hfac)₂.2H₂O, Mg(hfac)₂.tetraglyme, Mg(hfac)₂.2H₂O.2diglyme, Mg(mhd)₂, Mg(mhd)₂.2H₂O, Mg(mhd)₂.tetraglyme, Mg(mhd)₂.2H₂O.2diglyme, Mg(dibm)₂, Mg(tmod)₂, Mg(ibmp)₂, Mg(Et-diketiminate)₂, Mg(Et-ketoiminate)₂, Mg(di-iPr-amidinate)₂, Mg(di-tBu-amidinate)₂, Mg(di-iPr-formamidinate)₂, Mg(N,N′-Et₂-N″-Me₂-guanidinate)₂, Mg(N,N′-tBu₂-diazabutadienyl)₂, Mg(2-methyliminomethylpyrrolyl)₂, Mg(2-ethyliminomethylpyrrolyl)₂, Mg(2-isopropylimnomethylpyrrolyl)₂, and combinations thereof;
the fluorinated metal precursor being selected from the group consisting of titanium tetrafluoride (TiF₄), titanium cyclopentadienyl trifluoride (TiCpF₃), titanium methylcyclopentadienyl trifluoride (TiMeCpF₃), titanium acetylacetonate trifluoride [Ti(acac)F₃], titanium 2,2,6,6-tetramethylhepta-3,5-dionate trifluoride [Ti(tmhd)F₃], titanium (amino)pent-3-en-2-one trifluoride [Ti(AcNac)F₃], titanium (methylamino)pent-3-en-2-one trifluoride [Ti(Me-AcNac)F₃], titanium (ethylamino)pent-3-en-2-one trifluoride [Ti(Et-AcNac)F₃], titanium (4N-aminopent-3-en-2N-iminato) trifluoride [Ti(NacNac)F₃], titanium (4N-ethylaminopent-3-en-2N-ethyliminato) trifluoride [Ti(Et-NacNac)F₃], titanium (diisopropylamidinato) trifluoride [Ti(iPrN═CMe-NiPr)F₃], titanium (diisopropylformamidinato) trifluoride [Ti(iPrN═CH—NiPr)F₃], titanium (diisopropylguanidinato) trifluoride [Ti(iPrN═C(NMe₂)-NiPr)F₃], titanium 2-methyliminomethylpyrrolyl trifluoride [Ti(2-MeN═CH—(C₄H₃N))F₃], titanium 2-ethyliminomethylpyrrolyl trifluoride [Ti(2-EtN═CH—(C₄H₃N))F₃], titanium 2-isopropyliminomethylpyrrolyl trifluoride [Ti(2-iPrN═CH—(C₄H₃N))F₃], tantalum pentafluoride (TaF₅), tantalum cyclopentadienyl tetrafluoride (TaCpF₄), tantalum methylcyclopentadienyl tetrafluoride (TaMeCpF₄), tantalum acetylacetonate tetrafluoride [Ta(acac)F₄], tantalum 2,2,6,6-tetramethylhepta-3,5-dionate tetrafluoride [Ta(tmhd)F₄], tantalum aminopent-3-en-2-one tetrafluoride [Ta(AcNac)F₄], tantalum methylaminopent-3-en-2-one tetrafluoride [Ta(Me-AcNac)F₄], tantalum ethylaminopent-3-en-2-one tetrafluoride [Ta(Et-AcNac)F₄], tantalum 4N-aminopent-3-en-2N-iminato tetrafluoride [Ta(NacNac)F₄], tantalum 4N-ethylaminopent-3-en-2N-ethyliminato tetrafluoride [Ta(Et-NacNac)F₄], tantalum diisopropylamidinato tetrafluoride [Ta(iPrN═CMe-NiPr)F₄)], tantalum diisopropylformamidinato tetrafluoride [Ta(iPrN═CH—NiPr)F₄], tantalum diisopropylguanidinato tetrafluoride [Ta(iPrN═C(NMe₂)-NiPr)F₄], tantalum 2-methyliminomethylpyrrolyl tetrafluoride [Ta(2-MeN═CH—(C₄H₃N))F₄], tantalum 2-ethyliminomethylpyrrolyl tetrafluoride [Ta(2-EtN═CH—(C₄H₃N))F₄], tantalum 2-isopropyliminomethylpyrrolyl tetrafluoride [Ta(2-iPrN═CH—(C₄H₃N))F₄], tantalum biscyclopentadienyl trifluoride (TaCp₂F₃), tantalum bismethylcyclopentadienyl trifluoride [Ta(MeCp)₂F₃], tantalum bisacetylacetonate trifluoride [Ta(acac)₂F₃], tantalum bis 2,2,6,6-tetramethylhepta-3,5-dionate trifluoride [Ta(tmhd)₂F₃], tantalum bis(aminopent-3-en-2-one) trifluoride [Ta(AcNac)₂F₃], tantalum bis (methylaminopent-3-en-2-one) trifluoride [Ta(Me-AcNac)₂F₃], tantalum bis(ethylaminopent-3-en-2-one) trifluoride [Ta(Et-AcNac)₂F₃], tantalum bis(4N-aminopent-3-en-2N-iminato) trifluoride [Ta(NacNac)₂F₃], tantalum bis(4N-ethylaminopent-3-en-2N-ethyliminato) trifluoride [Ta(Et-NacNac)₂F₃], tantalum bis(diisopropylamidinato) trifluoride [Ta(iPrN═CMe-NiPr)F₃], tantalum bis(diisopropylformamidinato) trifluoride [Ta(iPrN═CH—NiPr)F₃], tantalum bis(diisopropylguanidinato) trifluoride [Ta(iPrN═C(NMe₂)-NiPr)F₃], tantalum bis(2-methyliminomethylpyrrolyl) trifluoride [Ta(2-MeN═CH—(C₄H₃N))F₃], tantalum bis(2-ethyliminomethylpyrrolyl) trifluoride [Ta(2-EtN═CH—(C₄H₃N))F₃], tantalum bis(2-isopropyliminomethylpyrrolyl) trifluoride [Ta(2-iPrN═CH—(C₄H₃N))F₃], niobium pentafluoride (NbF₅), niobium cyclopentadienyl tetrafluoride (NbCpF₄), niobium methylcyclopentadienyl tetrafluoride (NbMeCpF₄), niobium acetylacetonate tetrafluoride [Nb(acac)F₄], niobium 2,2,6,6-tetramethylhepta-3,5-dionate tetrafluoride [Nb(tmhd)F₄], niobium aminopent-3-en-2-one tetrafluoride [Nb(AcNac)F₄], niobium methylaminopent-3-en-2-one tetrafluoride [Nb(Me-AcNac)F₄], niobium ethylaminopent-3-en-2-one tetrafluoride [Nb(Et-AcNac)F₄], niobium 4N-aminopent-3-en-2N-iminato tetrafluoride [Nb(NacNac)F₄], niobium 4N-ethylaminopent-3-en-2N-ethyliminato tetrafluoride [Nb(Et-NacNac)F₄], niobium diisopropylamidinato tetrafluoride [Nb(iPrN═CMe-NiPr)F₄], niobium diisopropylformamidinato tetrafluoride [Nb(iPrN═CH—NiPr)F₄], niobium diisopropylguanidinato tetrafluoride [Nb(iPrN═C(NMe₂)-NiPr)F₄], niobium 2-methyliminomethylpyrrolyl tetrafluoride [Nb (2-MeN═CH—(C₄H₃N))F₄], niobium 2-ethyliminomethylpyrrolyl tetrafluoride [Nb (2-EtN═CH—(C₄H₃N))F₄], niobium 2-isopropyliminomethylpyrrolyl tetrafluoride [Nb (2-iPrN═CH—(C₄H₃N))F₄], niobium biscyclopentadienyl trifluoride (NbCp₂F₃), niobium bismethylcyclopentadienyl trifluoride [Nb(MeCp)₂F₃], niobium bisacetylacetonate trifluoride [Nb(acac)₂F₃], niobium bis(2,2,6,6-tetramethylhepta-3,5-dionate) trifluoride [Nb(tmhd)₂F₃], niobium bis(aminopent-3-en-2-one) trifluoride [Nb(AcNac)₂F₃], niobium bis(methylaminopent-3-en-2-one) trifluoride [Nb(Me-AcNac)₂F₃], niobium bis(ethylaminopent-3-en-2-one) trifluoride [Nb(Et-AcNac)₂F₃], niobium bis(4N-aminopent-3-en-2N-iminato) trifluoride [Nb(NacNac)₂F₃], niobium bis(4N-ethylaminopent-3-en-2N-ethyliminato) trifluoride [Nb(Et-NacNac)₂F₃], niobium bis(diisopropylamidinato) trifluoride [Nb(iPrN═CMe-NiPr)F₃], niobium bis(diisopropylformamidinato) trifluoride [Nb(iPrN═CH—NiPr)F₃], niobium bis(diisopropylguanidinato) trifluoride [Nb(iPrN═C(NMe₂)-NiPr)F₃], niobium bis(2-methyliminomethylpyrrolyl) trifluoride [Nb (2-MeN═CH—(C₄H₃N))F₃], niobium bis(2-ethyliminomethylpyrrolyl) trifluoride [Nb (2-EtN═CH—(C₄H₃N))F₃], niobium bis(2-isopropyliminomethylpyrrolyl) trifluoride [Nb (2-iPrN═CH—(C₄H₃N))F₃], xenon difluoride (XeF₂), xenon cyclopentadienyl fluoride (XeCpF), xenon methylcyclopentadienyl fluoride (XeMeCpF), xenon acetylacetonate fluoride [Xe(acac)F], xenon 2,2,6,6-tetramethylhepta-3,5-dionate fluoride [Xe(tmhd)F], xenon aminopent-3-en-2-one fluoride [Xe(AcNac)F], xenon methylaminopent-3-en-2-one fluoride [Xe(Me-AcNac)F], xenon ethylaminopent-3-en-2-one fluoride [Xe(Et-AcNac)F], xenon 4N-aminopent-3-en-2N-iminato fluoride [Xe(NacNac)F], xenon 4N-ethylaminopent-3-en-2N-ethyliminato fluoride [Xe(Et-NacNac)F], xenon 2-methyliminomethylpyrrolyl fluoride [Xe (2-MeN═CH—(C₄H₃N))F], xenon 2-ethyliminomethylpyrrolyl fluoride [Xe (2-EtN═CH—(C₄H₃N))F], xenon 2-isopropyliminomethylpyrrolyl fluoride [Xe (2-iPrN═CH—(C₄H₃N))F], antimony pentafluoride (SbF₅), antimony cyclopentadienyl tetrafluoride (SbCpF₄), antimony methylcyclopentadienyl tetrafluoride (SbMeCpF₄), antimony acetylacetonate tetrafluoride [Sb(acac)F₄], antimony 2,2,6,6-tetramethylhepta-3,5-dionate tetrafluoride [Sb(tmhd)F₄], antimony (amino)pent-3-en-2-one tetrafluoride [Sb(AcNac)F₄], antimony (methylamino)pent-3-en-2-one tetrafluoride [Sb(Me-AcNac)F₄], antimony (ethylamino)pent-3-en-2-one tetrafluoride [Sb(Et-AcNac)F₄], antimony 4N-aminopent-3-en-2N-iminato tetrafluoride (Sb(NacNac)F₄), antimony 4N-ethylaminopent-3-en-2N-ethyliminato tetrafluoride (Sb(Et-NacNac)F₄), antimony diisopropylamidinato tetrafluoride (Sb(iPrN═CMe-NiPr)F₄), antimony diisopropylformamidinato tetrafluoride (Sb(iPrN═CH—NiPr)F₄), antimony diisopropylguanidinato tetrafluoride (Sb(iPrN═C(NMe₂)-NiPr)F₄), antimony 2-methyliminomethylpyrrolyl tetrafluoride (Sb (2-MeN═CH—(C₄H₃N))F₄), antimony 2-ethyliminomethylpyrrolyl tetrafluoride (Sb (2-EtN═CH—(C₄H₃N))F₄), antimony 2-isopropyliminomethylpyrrolyl tetrafluoride [Sb (2-iPrN═CH—(C₄H₃N))F₄], antimony bis(cyclopentadienyl)trifluoride (SbCp₂F₃), antimony bis(methylcyclopentadienyl)trifluoride (Sb (MeCp)₂F₃), antimony bis(acetylacetonate)trifluoride (Sb(acac)₂F₃), antimony bis(2,2,6,6-tetramethylhepta-3,5-dionate) trifluoride (Sb(tmhd)₂F₃), antimony bis(amino)pent-3-en-2-one) trifluoride (Sb(AcNac)₂F₃), antimony bis(methylamino)pent-3-en-2-one) trifluoride (Sb(Me-AcNac)₂F₃), antimony bis(ethylamino)pent-3-en-2-one) trifluoride (Sb(Et-AcNac)₂F₃), antimony bis(4N-aminopent-3-en-2N-iminato) trifluoride (Sb(NacNac)₂F₃), antimony bis(4N-ethylaminopent-3-en-2N-ethyliminato) trifluoride (Sb(Et-NacNac)₂F₃), antimony bis(diisopropylamidinato) trifluoride (Sb(iPrN═CMe-NiPr)₂F₃), antimony bis(diisopropylformamidinato) trifluoride (Sb(iPrN═CH—NiPr)₂F₃), antimony bis(diisopropylguanidinato) trifluoride (Sb(iPrN═C(NMe₂)-NiPr)₂F₃), antimony bis(2-methyliminomethylpyrrolyl) trifluoride (Sb (2-MeN═CH—(C₄H₃N))F₃), antimony bis(2-ethyliminomethylpyrrolyl) trifluoride (Sb (2-EtN═CH—(C₄H₃N))F₃), antimony bis(2-isopropyliminomethylpyrrolyl) trifluoride (Sb (2-iPrN═CH—(C₄H₃N))F₃), and hafnium tetrafluoride, preferably titanium tetrafluoride, tantalum pentafluoride, niobium pentafluoride, xenon difluoride, antimony pentafluoride, and hafnium tetrafluoride;
introducing the alkaline earth metal precursor and the fluorinated metal precursor into a pre-chamber prior to introducing them to the reaction chamber;
the pre-chamber having a temperature below approximately 150° C.;
the alkaline earth metal fluoride film is deposited onto the one or more substrates by a chemical vapor deposition process or by an atomic layer deposition process;
the chemical vapor deposition process or the atomic layer deposition process being plasma enhanced;
the chemical vapor deposition process or the atomic layer deposition process being performed at a temperature below 250° C., preferably below 200° C.;
the chemical vapor deposition process or atomic layer deposition process being performed at a pressure between about 0.0001 Torr (0.013 Pa) and about 1000 Torr (13.33×10⁴ Pa), preferably between about 0.1 Torr (13.33 Pa) and about 300 Torr (40×10³ Pa);
introducing a reactant into the reaction chamber;
the reactant being selected from the group consisting of F₂, NF₃, COF₂, BF₃, C₂F₆, C₂F₄, and C₃F₈;
the reactant being selected from the group consisting of H₂, NH₃, SiH₄, Si₂H₆, Si₃H₈, O₂, O₃, H₂O, and H₂O₂;
introducing into the reaction chamber one or more elements;
the one or more elements being oxygen, nitrogen, aluminum, or combinations thereof; and
decreasing a refractive index of the alkaline earth metal fluoride film by a post treatment process.

### BRIEF DESCRIPTION OF THE DRAWINGS

For a further understanding of the nature and objects of the present invention, reference should be made to the following detailed description, taken in conjunction with the accompanying graphs, and wherein:

FIG. 1 is a schematic representation of one embodiment of the pre-chamber;

FIG. 2 is a graph of the atomic composition of a MgF₂ film deposited on SiO₂ by conventional CVD as determined by Auger Electron Spectroscopy (AES) at 200° C./5 Torr (667 Pa); and

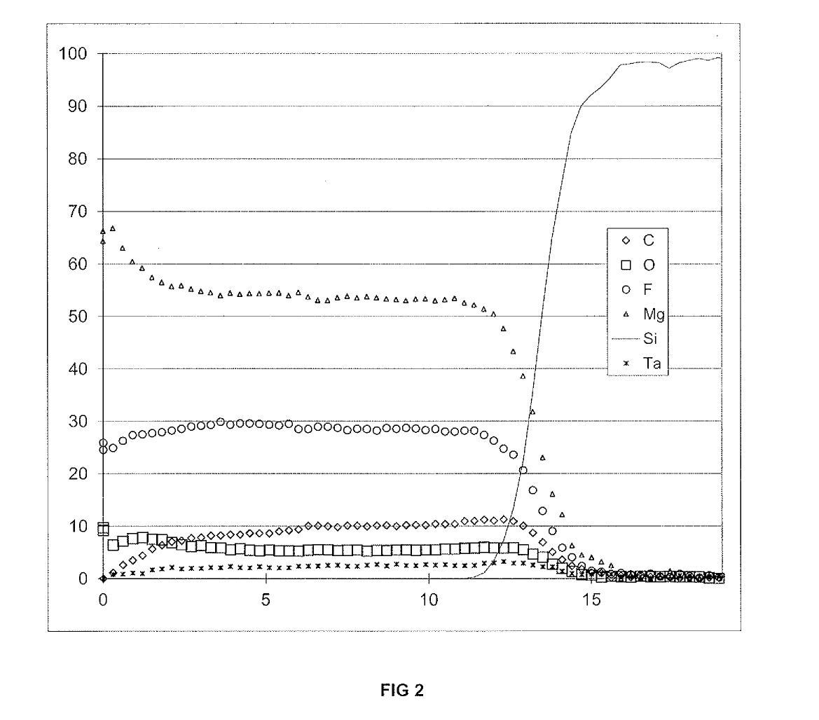

FIG. 3 is a graph of the atomic composition of a MgF₂ film deposited on SiO₂ by one embodiment of the disclosed methods as determined by AES at 200° C./5 Torr (667 Pa).

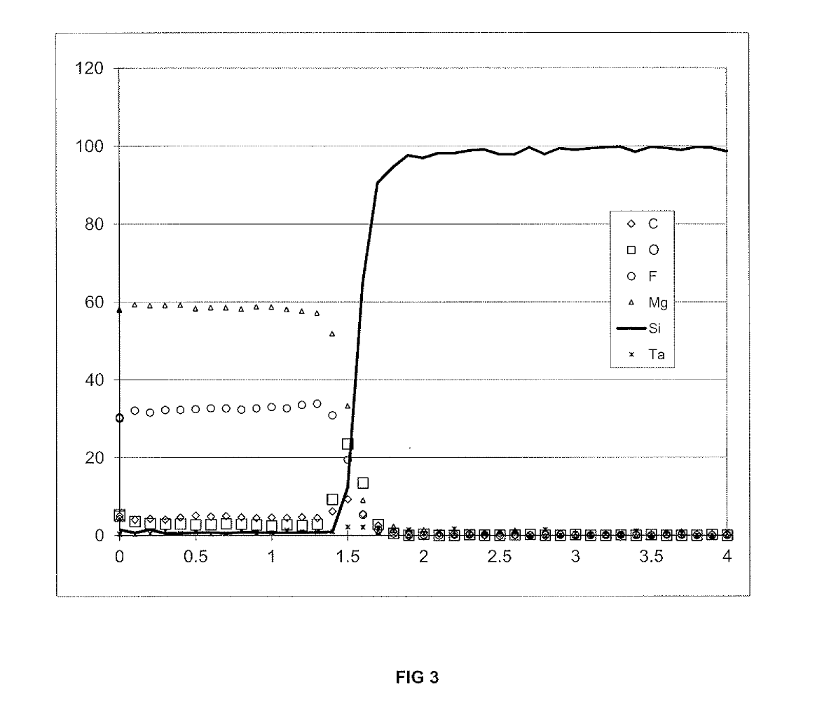

### DETAILED DESCRIPTION OF PREFERRED EMBODIMENTS

Disclosed are methods of depositing alkaline earth metal fluoride films onto substrates. An alkaline earth metal precursor and a fluorinated metal precursor are introduced into vapor deposition reaction chamber to deposit the alkaline earth metal fluoride film onto the one or more substrates.

The alkaline earth metal precursors have the general formula:

M L¹ₒₓY¹ₚ

wherein:
M is magnesium (Mg), calcium (Ca), strontium (Sr), or barium (Ba), preferably M is magnesium;
each L¹ is independently selected from the group consisting of acetylacetonate, enaminoketonate, β-diketiminate, diazabutadienyl, amidinate, formamidinate, guanidinate, iminomethylpyrrolyl, cyclopentadienyl, pentadienyl, cyclohexadienyl, hexadienyl, cycloheptadienyl, heptadienyl, cyclooctadienyl, and octadienyl, each of which may be substituted by C1-C4 linear, branched, or cyclic alkyl group; C1-C4 linear, branched, or cyclic mono, bis, or tris-alkylsilyl group; C1-C4 linear, branched, or cyclic alkylamino group; or a C1-C4 linear, branched, or cyclic fluoroalkyl group;
each Y¹ is a Lewis base independently selected from monoglyme, polyglyme, pyridine, THF, diethylether, or H₂O;
ox is an integer representing an oxidation state of the alkaline earth metal M; and
p is a number selected between 0 and 4, preferably 0, 1, 2, or 4.

Exemplary alkaline earth metal precursors include MgCp₂, Mg(MeCp)₂, Mg(Cp*)₂, Mg(EtCp)₂, Mg(nPrCp)₂, Mg(iPrCp)₂, Mg(nBuCp)₂, Mg(isoBuCp)₂, Mg(secBuCp)₂, Mg(op)₂, Mg(acac)₂, Mg(acac)₂.2H₂O, Mg(acac)₂.tetraglyme, Mg(acac)₂.2H₂O.2diglyme, Mg(tmhd)₂, Mg(tmhd)₂.2H₂O, Mg(tmhd)₂.tetraglyme, Mg(tmhd)₂.2H₂O.2diglyme, Mg(od)₂, Mg(tfac)₂, Mg(tfac)₂.2H₂O, Mg(tfac)₂.tetraglyme, Mg(tfac)₂.2H₂O.2diglyme, Mg(hfac)₂, Mg(hfac)₂.2H₂O, Mg(hfac)₂.tetraglyme, Mg(hfac)₂.2H₂O.2diglyme, Mg(mhd)₂, Mg(mhd)₂.2H₂O, Mg(mhd)₂.tetraglyme, Mg(mhd)₂.2H₂O.2diglyme, Mg(dibm)₂, Mg(tmod)₂, Mg(ibmp)₂, Mg(Et-diketiminate)₂, Mg(Et-ketoiminate)₂, Mg(di-iPr-amidinate)₂, Mg(di-tBu-amidinate)₂, Mg(di-iPr-formamidinate)₂, Mg(N,N′-Et₂-N″-Me₂-guanidinate)₂, Mg(N,N′-tBu₂-diazabutadienyl)₂, Mg(2-methyliminomethylpyrrolyl)₂, Mg(2-ethyliminomethylpyrrolyl)₂, Mg(2-isopropylimnomethylpyrrolyl)₂, and combinations thereof. These alkaline earth metal precursors are either commercially available or may be synthesized by methods known in the art.

The fluorinated metal precursors have the general formula:

NFₒₓₓ₋ₓL²_{oxx-y}Yₚ

wherein:
N is Titanium (Ti), Tantalum (Ta), Niobium (Nb), Xenon (Xe), Antimony (Sb), or Hafnium (Hf);
each L² is independently selected from the group consisting of acetylacetonate, enaminoketonate, β-diketiminate, diazabutadienyl, amidinate, formamidinate, guanidinate, iminomethylpyrrolyl, cyclopentadienyl, pentadienyl, cyclohexadienyl, hexadienyl, cycloheptadienyl, heptadienyl, cyclooctadienyl, and octadienyl, each of which may be substituted by C1-C4 linear, branched, or cyclic alkyl group; C1-C4 linear, branched, or cyclic mono, bis, or tris-alkylsilyl group; C1-C4 linear, branched, or cyclic alkylamino group; or a C1-C4 linear, branched, or cyclic fluoroalkyl group;
each Y² is a Lewis base selected from monoglyme, polyglyme, pyridine, THF, dimethylether, or diethyl ether;
oxx is an integer representing the oxidation state of the metal N;
x is an integer selected between 1 and oxx;
y is an integer selected between 0 and oxx;
the sum of x and y is equal to oxx;
p is a number selected between 0 and 4; and
the alkaline earth metal precursor is not Mg(tmhd)₂ when the fluorinated metal precursor is TiF₄ or TaF₅.

Exemplary fluorinated titanium precursors include titanium tetrafluoride (TiF₄), titanium cyclopentadienyl trifluoride (TiCpF₃), titanium methylcyclopentadienyl trifluoride (TiMeCpF₃), titanium acetylacetonate trifluoride [Ti(acac)F₃], titanium 2,2,6,6-tetramethylhepta-3,5-dionate trifluoride [Ti(tmhd)F₃], titanium (amino)pent-3-en-2-one trifluoride [Ti(AcNac)F₃], titanium (methylamino)pent-3-en-2-one trifluoride [Ti(Me-AcNac)F₃], titanium (ethylamino)pent-3-en-2-one trifluoride [Ti(Et-AcNac)F₃], titanium (4N-aminopent-3-en-2N-iminato) trifluoride [Ti(NacNac)F₃], titanium (4N-ethylaminopent-3-en-2N-ethyliminato) trifluoride [Ti(Et-NacNac)F₃], titanium (diisopropylamidinato) trifluoride [Ti(iPrN═CMe-NiPr)F₃], titanium (diisopropylformamidinato) trifluoride [Ti(iPrN═CH—NiPr)F₃], titanium (diisopropylguanidinato) trifluoride [Ti(iPrN═C(NMe₂)—NiPr)F₃], titanium 2-methyliminomethylpyrrolyl trifluoride [Ti(2-MeN═CH—(C₄H₃N))F₃], titanium 2-ethyliminomethylpyrrolyl trifluoride [Ti(2-EtN═CH—(C₄H₃N))F₃], and titanium 2-isopropyliminomethylpyrrolyl trifluoride [Ti(2-iPrN═CH—(C₄H₃N))F₃].

Exemplary fluorinated tantalum precursors include tantalum pentafluoride

(TaF₅), tantalum cyclopentadienyl tetrafluoride (TaCpF₄), tantalum methylcyclopentadienyl tetrafluoride (TaMeCpF₄), tantalum acetylacetonate tetrafluoride [Ta(acac)F₄], tantalum 2,2,6,6-tetramethylhepta-3,5-dionate tetrafluoride [Ta(tmhd)F₄], tantalum aminopent-3-en-2-one tetrafluoride [Ta(AcNac)F₄], tantalum methylaminopent-3-en-2-one tetrafluoride [Ta(Me-AcNac)F₄], tantalum ethylaminopent-3-en-2-one tetrafluoride [Ta(Et-AcNac)F₄], tantalum 4N-aminopent-3-en-2N-iminato tetrafluoride [Ta(NacNac)F₄], tantalum 4N-ethylaminopent-3-en-2N-ethyliminato tetrafluoride [Ta(Et-NacNac)F₄], tantalum diisopropylamidinato tetrafluoride [Ta(iPrN═CMe-NiPr)F₄)], tantalum diisopropylformamidinato tetrafluoride [Ta(iPrN═CH—NiPr)F₄], tantalum diisopropylguanidinato tetrafluoride [Ta(iPrN═C(NMe₂)-NiPr)F₄], tantalum 2-methyliminomethylpyrrolyl tetrafluoride [Ta(2-MeN═CH—(C₄H₃N))F₄], tantalum 2-ethyliminomethylpyrrolyl tetrafluoride [Ta(2-EtN═CH—(C₄H₃N))F₄], tantalum 2-isopropyliminomethylpyrrolyl tetra]fluoride [Ta(2-iPrN═CH—(C₄H₃N))F₄], tantalum biscyclopentadienyl trifluoride (TaCp₂F₃), tantalum bismethylcyclopentadienyl trifluoride [Ta(MeCp)₂F₃], tantalum bisacetylacetonate trifluoride [Ta(acac)₂F₃], tantalum bis 2,2,6,6-tetramethylhepta-3,5-dionate trifluoride [Ta(tmhd)₂F₃], tantalum bis(aminopent-3-en-2-one) trifluoride [Ta(AcNac)₂F₃], tantalum bis (methylaminopent-3-en-2-one) trifluoride [Ta(Me-AcNac)₂F₃], tantalum bis(ethylaminopent-3-en-2-one) trifluoride [Ta(Et-AcNac)₂F₃], tantalum bis(4N-aminopent-3-en-2N-iminato) trifluoride [Ta(NacNac)₂F₃], tantalum bis(4N-ethylaminopent-3-en-2N-ethyliminato) trifluoride [Ta(Et-NacNac)₂F₃], tantalum bis(diisopropylamidinato) trifluoride [Ta(iPrN═CMe-NiPr)F₃], tantalum bis(diisopropylformamidinato) trifluoride [Ta(iPrN═CH—NiPr)F₃], tantalum bis(diisopropylguanidinato) trifluoride [Ta(iPrN═C(NMe₂)-NiPr)F₃], tantalum bis(2-methyliminomethylpyrrolyl) trifluoride [Ta(2-MeN═CH—(C₄H₃N))F₃], tantalum bis(2-ethyliminomethylpyrrolyl) trifluoride [Ta(2-EtN═CH—(C₄H₃N))F₃], and tantalum bis(2-isopropyliminomethylpyrrolyl) trifluoride [Ta(2-iPrN═CH—(C₄H₃N))F₃].

Exemplary fluorinated niobium precursors include niobium pentafluoride (NbF₅), niobium cyclopentadienyl tetrafluoride (NbCpF₄), niobium methylcyclopentadienyl tetrafluoride (NbMeCpF₄), niobium acetylacetonate tetrafluoride [Nb(acac)F₄], niobium 2,2,6,6-tetramethylhepta-3,5-dionate tetrafluoride [Nb(tmhd)F₄], niobium aminopent-3-en-2-one tetrafluoride [Nb(AcNac)F₄], niobium methylaminopent-3-en-2-one tetrafluoride [Nb(Me-AcNac)F₄], niobium ethylaminopent-3-en-2-one tetrafluoride [Nb(Et-AcNac)F₄], niobium 4N-aminopent-3-en-2N-iminato tetrafluoride [Nb(NacNac)F₄], niobium 4N-ethylaminopent-3-en-2N-ethyliminato tetrafluoride [Nb(Et-NacNac)F₄], niobium diisopropylamidinato tetrafluoride [Nb(iPrN═CMe-NiPr)F₄], niobium diisopropylformamidinato tetrafluoride [Nb(iPrN═CH—NiPr)F₄], niobium diisopropylguanidinato tetrafluoride [Nb(iPrN═C(NMe₂)-NiPr)F₄], niobium 2-methyliminomethylpyrrolyl tetrafluoride [Nb (2-MeN═CH—(C₄H₃N))F₄], niobium 2-ethyliminomethylpyrrolyl tetrafluoride [Nb (2-EtN═CH—(C₄H₃N))F₄], niobium 2-isopropyliminomethylpyrrolyl tetrafluoride [Nb (2-iPrN═CH—(C₄H₃N))F₄], niobium biscyclopentadienyl trifluoride (NbCp₂F₃), niobium bismethylcyclopentadienyl trifluoride [Nb(MeCp)₂F₃], niobium bisacetylacetonate trifluoride [Nb(acac)₂F₃], niobium bis(2,2,6,6-tetramethylhepta-3,5-dionate) trifluoride [Nb(tmhd)₂F₃], niobium bis(aminopent-3-en-2-one) trifluoride [Nb(AcNac)₂F₃], niobium bis(methylaminopent-3-en-2-one) trifluoride [Nb(Me-AcNac)₂F₃], niobium bis(ethylaminopent-3-en-2-one) trifluoride [Nb(Et-AcNac)₂F₃], niobium bis(4N-aminopent-3-en-2N-iminato) trifluoride [Nb(NacNac)₂F₃], niobium bis(4N-ethylaminopent-3-en-2N-ethyliminato) trifluoride [Nb(Et-NacNac)₂F₃], niobium bis(diisopropylamidinato) trifluoride [Nb(iPrN═CMe-NiPr)F₃], niobium bis(diisopropylformamidinato) trifluoride [Nb(iPrN═CH—NiPr)F₃], niobium bis(diisopropylguanidinato) trifluoride [Nb(iPrN═C(NMe₂)-NiPr)F₃], niobium bis(2-methyliminomethylpyrrolyl) trifluoride [Nb (2-MeN═CH—(C₄H₃N))F₃], niobium bis(2-ethyliminomethylpyrrolyl) trifluoride [Nb (2-EtN═CH—(C₄H₃N))F₃], and niobium bis(2-isopropyliminomethylpyrrolyl) trifluoride [Nb (2-iPrN═CH—(C₄H₃N))F₃].

Exemplary fluorinated xenon precursors include xenon difluoride (XeF₂), xenon cyclopentadienyl fluoride (XeCpF), xenon methylcyclopentadienyl fluoride (XeMeCpF), xenon acetylacetonate fluoride [Xe(acac)F], xenon 2,2,6,6-tetramethylhepta-3,5-dionate fluoride [Xe(tmhd)F], xenon aminopent-3-en-2-one fluoride [Xe(AcNac)F], xenon methylaminopent-3-en-2-one fluoride [Xe(Me-AcNac)F], xenon ethylaminopent-3-en-2-one fluoride [Xe(Et-AcNac)F], xenon 4N-aminopent-3-en-2N-iminato fluoride [Xe(NacNac)F], xenon 4N-ethylaminopent-3-en-2N-ethyliminato fluoride [Xe(Et-NacNac)F], xenon 2-methyliminomethylpyrrolyl fluoride [Xe (2-MeN═CH—(C₄H₃N))F], xenon 2-ethyliminomethylpyrrolyl fluoride [Xe (2-EtN═CH—(C₄H₃N))F], and xenon 2-isopropyliminomethylpyrrolyl fluoride [Xe (2-iPrN═CH—(C₄H₃N))F].

Exemplary fluorinated antimony precursors include antimony pentafluoride (SbF₅), antimony cyclopentadienyl tetrafluoride (SbCpF₄), antimony methylcyclopentadienyl tetrafluoride (SbMeCpF₄), antimony acetylacetonate tetrafluoride [Sb(acac)F₄], antimony 2,2,6,6-tetramethylhepta-3,5-dionate tetrafluoride [Sb(tmhd)F₄], antimony (amino)pent-3-en-2-one tetrafluoride [Sb(AcNac)F₄], antimony (methylamino)pent-3-en-2-one tetrafluoride [Sb(Me-AcNac)F₄], antimony (ethylamino)pent-3-en-2-one tetrafluoride [Sb(Et-AcNac)F₄], antimony 4N-aminopent-3-en-2N-iminato tetrafluoride (Sb(NacNac)F₄), antimony 4N-ethylaminopent-3-en-2N-ethyliminato tetrafluoride (Sb(Et-NacNac)F₄), antimony diisopropylamidinato tetrafluoride (Sb(iPrN═CMe-NiPr)F₄), antimony diisopropylformamidinato tetrafluoride (Sb(iPrN═CH—NiPr)F₄), antimony diisopropylguanidinato tetrafluoride (Sb(iPrN═C(NMe₂)-NiPr)F₄), antimony 2-methyliminomethylpyrrolyl tetrafluoride (Sb (2-MeN═CH—(C₄H₃N))F₄), antimony 2-ethyliminomethylpyrrolyl tetrafluoride (Sb (2-EtN═CH—(C₄H₃N))F₄), antimony 2-isopropyliminomethylpyrrolyl tetrafluoride [Sb (2-iPrN═CH—(C₄H₃N))F₄], antimony bis(cyclopentadienyl)trifluoride (SbCp₂F₃), antimony bis(methylcyclopentadienyl)trifluoride (Sb (MeCp)₂F₃), antimony bis(acetylacetonate)trifluoride (Sb(acac)₂F₃), antimony bis(2,2,6,6-tetramethylhepta-3,5-dionate) trifluoride (Sb(tmhd)₂F₃), antimony bis(amino)pent-3-en-2-one) trifluoride (Sb(AcNac)₂F₃), antimony bis(methylamino)pent-3-en-2-one) trifluoride (Sb(Me-AcNac)₂F₃), antimony bis(ethylamino)pent-3-en-2-one) trifluoride (Sb(Et-AcNac)₂F₃), antimony bis(4N-aminopent-3-en-2N-iminato) trifluo ride (Sb(NacNac)₂F₃), antimony bis(4N-ethylaminopent-3-en-2N-ethyliminato) trifluoride (Sb(Et-NacNac)₂F₃), antimony bis(diisopropylamidinato) trifluoride (Sb(iPrN═CMe-NiPr)₂F₃), antimony bis(diisopropylformamidinato) trifluoride (Sb(iPrN═CH—NiPr)₂F₃), antimony bis(diisopropylguanidinato) trifluoride (Sb(iPrN═C(NMe₂)-NiPr)₂F₃), antimony bis(2-methyliminomethylpyrrolyl) trifluoride (Sb (2-MeN═CH—(C₄H₃N))F₃), antimony bis(2-ethyliminomethylpyrrolyl) trifluoride (Sb (2-EtN═CH—(C₄H₃N))F₃), and antimony bis(2-isopropyliminomethylpyrrolyl) trifluo ride (Sb (2-iPrN═CH—(C₄H₃N))F₃).

Exemplary fluorinated hafnium precursors include hafnium tetrafluoride (HfF₄), hafnium cyclopentadienyl trifluoride (HfCpF₃), hafnium methylcyclopentadienyl trifluoride (HfMeCpF₃), hafnium acetylacetonate trifluoride [Hf(acac)F₃], hafnium 2,2,6,6-tetramethylhepta-3,5-dionate trifluoride [Hf(tmhd)F₃], hafnium (amino)pent-3-en-2-one trifluoride [Hf(AcNac)F₃], hafnium (methylamino)pent-3-en-2-one trifluoride [Hf(Me-AcNac)F₃], hafnium (ethylamino)pent-3-en-2-one trifluoride [Hf(Et-AcNac)F₃], hafnium (4N-aminopent-3-en-2N-iminato) trifluoride [Hf(NacNac)F₃], hafnium (4N-ethylaminopent-3-en-2N-ethyliminato) trifluoride [Hf(Et-NacNac)F₃], hafnium (diisopropylamidinato) trifluoride [Hf(iPrN═CMe-NiPr)F₃], hafnium (diisopropylformamidinato) trifluoride [Hf(iPrN═CH—NiPr)F₃], hafnium (diisopropylguanidinato) trifluoride [Hf(iPrN═C(NMe₂)-NiPr)F₃], hafnium 2-methyliminomethylpyrrolyl trifluoride [Hf(2-MeN═CH—(C₄H₃N))F₃], hafnium 2-ethyliminomethylpyrrolyl trifluoride [Hf(2-EtN═CH—(C₄H₃N))F₃], and hafnium 2-isopropyliminomethylpyrrolyl trifluoride [Hf(2-iPrN═CH—(C₄H₃N))F₃].

Preferably, the fluorinated metal precursor is titanium tetrafluoride, tantalum pentafluoride, niobium pentafluoride, xenon difluoride, antimony pentafluoride, or hafnium tetrafluoride.

The fluorinated metal precursors are either commercially available or may be synthesized by methods known in the art. The fluorinated metal precursors may also be synthesized by the following methods:

Reacting a metal fluoride having the formula NFₒₓₓY²ₚ with one, less than one (between 0 and 1), or several equivalents of an alkaline earth metal precursor having the formula ML¹ₒₓY¹ₚ in a solvent selected from the group consisting of but without limitation alcohols, tetrahydrofuran, diethylether, and toluene and in the presence or not of a Lewis base Y, when L¹ and L² are the same.

ML¹ₒₓY¹ₚ

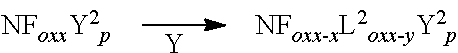

Alternatively, a metal fluorinated precursor having the formula NFₒₓₓY²ₚ may be reacted with one, less then one (between 0 and 1), or several equivalents of di-alkyl tin precursor having the formula SnR₂L¹₂ in a solvent selected from the group consisting of alcohols, tetrahydrofuran, diethylether, benzene, toluene and in presence or not of a Lewis base Y, when L¹ and L² are the same.

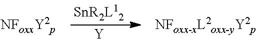

Either synthesis method alternative may further include removing the solvent; adding a chlorinated solvent (CH₂Cl₂, CHCl₃, CCl₄ for instance) to form a solution; filtering the solution; and removing the chlorinated solvent to form the metal fluorinated precursor product having the formula NFₒₓₓ₋ₓL²_{oxx-y}Y²ₚ. The method may further include distilling or sublimating the metal fluorinated precursor product.

The alkaline earth metal and fluorinated metal precursors may be used to deposit alkaline earth metal-containing films using any vapor deposition methods known to those of skill in the art. Examples of suitable deposition methods include without limitation, conventional chemical vapor deposition (CVD), plasma enhanced CVD (PECVD), low pressure chemical vapor deposition (LPCVD), atomic layer deposition (ALD), pulsed chemical vapor deposition (P-CVD), plasma enhanced atomic layer deposition (PE-ALD), or combinations thereof.

The precursors are introduced into the vapor deposition reaction chamber in vapor form. The precursors may be fed in liquid state to a vaporizer where they are vaporized before being introduced into the pre-chamber. Prior to vaporization, the precursors may optionally be mixed with one or more solvents, one or more metal sources, and a mixture of one or more solvents and one or more metal sources. The solvents may be selected from the group consisting of toluene, ethyl benzene, xylene, mesitylene, decane, dodecane, octane, hexane, pentane, or others. The resulting concentration may range from approximately 0.05 M to approximately 2 M. The metal source may include any metal precursors now known or later developed.

Alternatively, the precursors may be vaporized by passing a carrier gas into a container containing the precursor or by bubbling the carrier gas into the precursors. The carrier gas and precursors are then introduced into the pre-chamber. If necessary, the container may be heated to a temperature that permits the precursors to be in a liquid phase and to have a sufficient vapor pressure. The carrier gas may include, but is not limited to, Ar, He, N₂, and mixtures thereof. The precursors may optionally be mixed in the container with a solvent, another metal precursor, or a mixture thereof. The container may be maintained at temperatures in the range of, for example, 0-150° C. Those skilled in the art recognize that the temperature of the container may be adjusted in a known manner to control the amount of precursor vaporized.

The precursors are introduced as vapors into a reaction chamber containing at least one substrate. The reaction chamber may be any enclosure or chamber of a device in which deposition methods take place, such as, without limitation, a parallel-plate type reactor, a cold-wall type reactor, a hot-wall type reactor, a single-wafer reactor, a multi-wafer reactor, or other such types of deposition systems.

The type of substrate upon which the film will be deposited will vary depending on the final use intended. In some embodiments, the substrate may be chosen from oxides which are used as dielectric materials in Metal Insulator Metal (MIM—a structure used in capacitors), dynamic random access memory (DRAM), ferroelectric random access memory (FeRam technologies or gate dielectrics in complementary metal-oxide-semiconductor (CMOS) technologies (for example, HfO₂ based materials, TiO₂ based materials, ZrO₂ based materials, rare earth oxide based materials, ternary oxide based materials, etc.) or from nitride-based films (for example, TaN) that are used as an oxygen barrier between copper and the low-k layer. Other substrates may be used in the manufacture of semiconductors, photovoltaics, LCD-TFT, or flat panel devices. Examples of such substrates include, but are not limited to, solid substrates such as metal substrates (for example, Au, Pd, Rh, Ru, W, Al, Ni, Ti, Co, Pt and metal silicides, such as TiSi₂, CoSi₂, NiSi, and NiSi₂); metal nitride containing substrates (for example, TaN, TiN, WN, TaCN, TiCN, TaSiN, and TiSiN); semiconductor materials (for example, Si, SiGe, GaAs, InP, diamond, GaN, and SiC); insulators (for example, SiO₂, Si₃N₄, SiON, HfO₂, Ta₂O₅, ZrO₂, TiO₂, Al₂O₃, and barium strontium titanate); or other substrates that include any number of combinations of these materials. The actual substrate utilized may also depend upon the specific precursor embodiment utilized. In many instances though, the preferred substrate utilized will be selected from silicon, silicon oxide, a metallic surface, glass, quartz, or a polymer surface, such as polyacrylate or polycarbonate.

The conditions within the reaction chamber are suitable for the alkaline earth metal precursor to react with the fluorinated metal precursor in order to deposit the alkaline earth metal fluoride film. In an ALD method, the reaction may take place between portions of the precursors. For example, a portion of the alkaline earth metal precursor may deposit on the substrate and the fluorinated metal precursor may react with that portion. The reaction chamber may be maintained at a pressure ranging from about 0.0001 Torr (0.013 Pa) to about 1000 Torr (13.33×10⁴ Pa), preferably from about 0.1 Torr (13.33 Pa) to about 300 Torr (40×10³ Pa). In addition, the temperature within the reaction chamber may range from about 25° C. to about 300° C., preferably between about 50° C. and about 250° C., and more preferably from about 100° C. to and about 200° C.

The temperature of the reaction chamber, and consequently the deposition process, may be controlled by either controlling the temperature of the substrate holder or controlling the temperature of the reactor wall. The reactor wall may be heated to a sufficient temperature to obtain the desired film at a sufficient growth rate and with desired physical state and composition. A non-limiting exemplary temperature range to which the reactor wall may be heated includes from approximately 25° C. to approximately 300° C. When a plasma deposition process is utilized, the deposition temperature may range from approximately 50° C. to approximately 250° C. Alternatively, when a thermal process is performed, the deposition temperature may range from approximately 100° C. to approximately 300° C.

Alternatively, the substrate may be heated to a sufficient temperature to obtain the desired earth metal fluoride film at a sufficient growth rate and with desired physical state and composition. Devices used to heat the substrate are known in the art. A non-limiting exemplary temperature range to which the substrate may be heated includes from 150° C. to 300° C. Preferably, the temperature of the substrate remains less than or equal to 250° C.

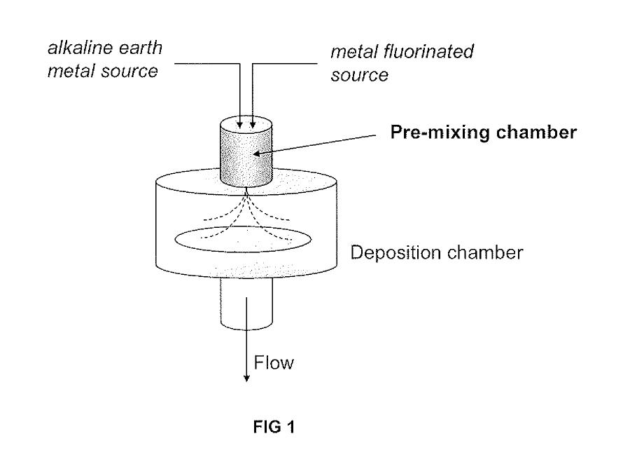

Prior to introduction into the reaction chamber, the vapors of the precursors may be introduced into a pre-chamber. The pre-chamber may be heated to a temperature below approximately 150° C. In the experimental testing performed to date, the pre-chamber has been a 5 cm×25 cm hollow cylinder made of quartz, similar to the pre-chamber shown in FIG. 1. As shown in FIG. 1, the pre-chamber is in fluid communication with the deposition chamber. The deposition chamber used had a 5 cm×55 cm cylinder shape. One of ordinary skill in the art will recognize that other materials that are compatible with the precursors may be used for the pre-chamber, including but not limited to stainless steel. One of ordinary skill will further recognize that the dimensions of the pre-chamber may be altered to suit the deposition chamber with which the pre-chamber is used. For example, at a larger scale, it may be necessary to add baffles or other flow direction devices to the inside of the hollow cylinder in order to maintain the results obtained herein.

Applicants believe that the alkaline earth metal precursor and the fluorinated metal precursor react in the pre-chamber to form one or more intermediary molecules. Non-reacted alkaline earth metal precursor, non-reacted metal precursor, and the reaction product flow from the pre-chamber to the deposition chamber to deposit the alkaline earth metal fluoride film. Applicants believe the reaction inside the pre-chamber proceeds as follows:

ML¹ₒₓY¹ₚ+NFₒₓₓY²ₚ→ML¹ₒₓY¹ₚ+NFₒₓₓYₚ+NFₒₓₓ₋ₓL²_{oxx-y}Y²ₚ

More specifically, Applicants believe the following reaction occurs inside the pre-chamber:

MgCp₂+2TaF₅→MgF₂+2TaCpF₄

and the following reaction occurs inside the deposition chamber:

MgCp₂+2TaCpF₄→MgF₂+2TaCp₂F₃

The resulting film contains less carbon and metal impurities than films produced without the use of the pre-chamber. However, the deposition rate is slower than the method performed without use of the pre-chamber. One of ordinary skill will be able to determine which method is preferable depending upon the quality of MgF₂ film to be formed.

The precursors may be mixed with reactants inside the reaction chamber. The reactant may contain a fluorine source, such as F₂, NF₃, COF₂, BF₃, C₂F₆, C₂F₄, C₃F₈. The reactant may also include a reducing agent, such as H₂, NH₃, or combinations thereof.

The reactant may be treated by plasma in order to decompose the reactant into its radical form. The plasma may be generated or present within the reaction chamber itself. Alternatively, the plasma may generally be at a location removed from the reaction chamber, for instance, in a remotely located plasma system. One of skill in the art will recognize methods and apparatus suitable for such plasma treatment.

For example, the reactant may be introduced into a direct plasma reaction chamber, which generates a plasma in the reaction chamber, to produce the plasma-treated reactant in the reaction chamber. Exemplary direct plasma reaction chambers include the Titan™ PECVD System produced by Trion Technologies. The reactant may be introduced and held in the reaction chamber prior to plasma processing. Alternatively, the plasma processing may occur simultaneously with the introduction of reactant. In-situ plasma is typically a 13.56 MHz RF capacitively coupled plasma that is generated between the showerhead and the substrate holder. The substrate or the showerhead may be the powered electrode depending on whether positive ion impact occurs. Typical applied powers in in-situ plasma generators are from approximately 100 W to approximately 1000 W. The disassociation of the reactant using in-situ plasma is typically less than achieved using a remote plasma source for the same power input and is therefore not as efficient in reactant disassociation as a remote plasma system, which may be beneficial for the deposition of metal-nitride-containing films on substrates easily damaged by plasma.

Alternatively, the plasma-treated reactant may be produced outside of the reaction chamber. The MKS Instruments' ASTRON®i reactive gas generator may be used to treat the reactant prior to passage into the reaction chamber. Operated at 2.45 GHz, 7 kW plasma power, and a pressure ranging from approximately 3 Torr to approximately 10 Torr, the reactant O₃ may be decomposed into three O⁻ radicals. Preferably, the remote plasma may be generated with a power ranging from about 1 kW to about 10 kW, more preferably from about 2.5 kW to about 7.5 kW.

Depending upon the desired use of the resulting film, the reactant may also include a pore forming agent, such as bicycloheptadiene or other non-saturated carbon ring molecules. The resulting film may undergo subsequent processing to form pores, such as UV curing or heating, but preferably not to temperatures above 250° C. Incorporation of pores in the alkaline earth metal fluoride film will lower the refractive index of the film. However, as oxygen penetration may damage the micro-lens in the CIS, porosity should be used judicially in such applications.

Other exemplary reactant species include, without limitation, metal precursors such as trimethyl aluminum (TMA) or other aluminum-containing precursors, other silicon-containing precursors, tertiary butylimido tris(diethylamino) tantalum (Ta[N(C₂H₅)₂]₃-[NC(CH₃)₃] or TBTDET), tantalum tetraethoxide dimethylaminoethoxide (TAT-DMAE), pentaethoxy tantalum (PET), tertiary butylimido tris(diethylamino) niobium (TBTDEN), pentaethoxy niobium (PEN), and any combination thereof.

When the desired film also contains oxygen, such as, for example and without limitation, magnesium oxide, the reactants may include an oxygen source which is selected from, but not limited to, O₂, O₃, H₂O, H₂O₂, acetic acid, formalin, para-formaldehyde, and combinations thereof. Alternatively, the oxygen source may be selected from O₂, H₂O, O₃, H₂O₂, carboxylic acid, or combinations thereof.

When the desired film also contains nitrogen, such as, for example and without limitation, MgON, the reactant may include a nitrogen source which is selected from, but not limited to, nitrogen (N₂), ammonia and alkyl derivatives thereof, hydrazine and alkyl derivatives thereof, N-containing radicals (for instance N, NH, NH₂), NO, N₂O, NO₂, amines, and any combination thereof.

When the desired film also contains carbon, such as, for example and without limitation, magnesium carbide, the reactant may include a carbon source which is selected from, but not limited to, methane, ethane, propane, butane, ethylene, propylene, t-butylene, isobutylene, CCl₄, and any combination thereof.

When the desired film also contains silicon, such as, for example and without limitation, MgSiOₓ, the reactant may include a silicon source which is selected from, but not limited to, SiH₄, Si₂H₆, Si₃H₈, tris(dimethylamino) silane (TriDMAS), bis(dimethylamino) silane (BDMAS), bis(diethylamino) silane (BDEAS), tetrakis-diethylamino silane (TDEAS), tris(dimethylamino) silane (TDMAS), tetrakis-ethylmethylamino silane (TEMAS), (SiH₃)₃N, (SiH₃)₂O, trisilylamine, disiloxane, trisilylamine, disilane, trisilane, an alkoxysilane SiHₓ(OR¹)₄₋ₓ, a silanol Si(OH)ₓ(OR¹)₄₋ₓ (preferably Si(OH)(OR¹)₃; more preferably Si(OH)(OtBu)₃ an aminosilane SiHₓ(NR¹R²)₄₋ₓ (where x is 1, 2, 3, or 4; R¹ and R² are independently H or a linear, branched or cyclic C1-C6 carbon chain; preferably TriDMAS, BTBAS, and/or BDEAS), and any combination thereof. The targeted film may alternatively contain germanium (Ge), in which case the above-mentioned Si-containing reactant species could be replaced by Ge-containing reactant species.

When the desired film also contains another metal, such as, for example and without limitation, Ti, Ta, Hf, Zr, Nb, Mg, Al, Sr, Y, Ba, Ca, As, Sb, Bi, Sn, Pb, or combinations thereof, the reactant may include a second precursor which is selected from, but not limited to, metal alkyls such as SbR^{i′}₃ or SnR^{i′}₄ (wherein each R^{i″} is independently H or a linear, branched, or cyclic C1-C6 carbon chain), metal alkoxides such as Sb(ORⁱ)₃ or Sn(ORⁱ)₄ (where each Rⁱ is independently H or a linear, branched, or cyclic C1-C6 carbon chain), and metal amines such as Sb(NR¹R²)(NR³R⁴)(NR⁵R⁶) or Ge(NR¹R²)(NR³R⁴)(NR⁵R⁶)(NR⁷R⁸) (where each R¹, R², R³, R⁴, R⁵, R⁶, R⁷, and R⁸ is independently H, a C1-C6 carbon chain, or a trialkylsilyl group, the carbon chain and trialkylsilyl group each being linear, branched, or cyclic), and any combination thereof.

The precursors and one or more reactants may be introduced into the reaction chamber simultaneously (chemical vapor deposition), sequentially (atomic layer deposition), or in other combinations. For example, the precursor may be introduced in one pulse and two additional metal sources may be introduced together in a separate pulse [modified atomic layer deposition]. Alternatively, the reaction chamber may already contain the reactant prior to introduction of the precursor. The reactant may be passed through a plasma system localized remotely from the reaction chamber, and decomposed to radicals. Alternatively, the precursor may be introduced to the reaction chamber continuously while other metal sources are introduced by pulse (pulsed-chemical vapor deposition). In each example, a pulse may be followed by a purge or evacuation step to remove excess amounts of the component introduced. In each example, the pulse may last for a time period ranging from about 0.01 s to about 10 s, alternatively from about 0.3 s to about 3 s, alternatively from about 0.5 s to about 2 s.

In an ALD or PEALD process, an annealing or flash annealing step may be performed between each ALD cycle or, preferably, after multiple ALD cycles (for instance every 2 to 10 ALD cycles). The number of deposition cycles performed between each annealing step may be tuned to maximize film properties and throughput. The substrate may be exposed to a temperature ranging from approximately 400° C. and approximately 1000° C. for a time ranging from approximately 0.1 second to approximately 120 seconds under an inert, a N-containing atmosphere, an O-containing atmosphere, or combinations thereof. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus.

In one non-limiting exemplary atomic layer deposition type process, the vapor phase of the alkaline earth metal precursor is introduced into the reaction chamber, where it is contacted with a suitable substrate. Excess precursor may then be removed from the reaction chamber by purging and/or evacuating the reaction chamber. The fluorine metal precursor is introduced into the reaction chamber where it reacts with the absorbed precursor in a self-limiting manner. Any excess fluorine metal precursor is removed from the reaction chamber by purging and/or evacuating the reaction chamber. If the desired film is an alkaline earth metal fluoride film, this two-step process may provide the desired film thickness or may be repeated until a film having the necessary thickness has been obtained.

Alternatively, if the desired film is an alkaline earth metal fluoride film containing a second metal, the two-step process above may be followed by introduction of the vapor of a metal-containing precursor into the reaction chamber. The metal-containing precursor will be selected based on the nature of the alkaline earth metal fluoride film being deposited and may include a carbon-containing precursor. After introduction into the reaction chamber, the metal-containing precursor is contacted with the substrate. Any excess metal-containing precursor is removed from the reaction chamber by purging and/or evacuating the reaction chamber. A reactant may be introduced into the reaction chamber to react with the metal-containing precursor. Excess reactant is removed from the reaction chamber by purging and/or evacuating the reaction chamber. If a desired film thickness has been achieved, the process may be terminated. However, if a thicker film is desired, the entire four-step process may be repeated. By alternating the provision of the alkaline earth metal precursor, fluorine metal precursor, and any option metal-containing precursors and reactants, a film of desired composition and thickness can be deposited.

The alkaline earth metal fluoride films resulting from the processes discussed above may include MgF₂, CaF₂, SrF₂, and BaF₂. One of ordinary skill in the art will recognize that by judicial selection of the appropriate precursor and co-reactant species, the desired film composition may be obtained.

### EXAMPLES

The following non-limiting examples are provided to further illustrate embodiments of the invention. However, the examples are not intended to be all inclusive and are not intended to limit the scope of the inventions described herein.

### Example 1

### Typical CVD Experiment

Deposition of MgF₂ was performed on native silicon oxide in CVD mode using Mg(MeCp)₂ as magnesium source and TaF₅ as fluorine source. Mg(MeCp)₂ was placed in a vessel heated at 45° C. and TaF₅ in a vessel at 60° C. Typical CVD conditions were used at temperatures ranging from 150 to 250° C. and pressure ranging from 1 Torr to 10 Torr. Auger Electron Spectroscopy (AES) was used to assess atomic composition of the films. As seen in Table 1 MgF₂ films contain a certain amount of Tantalum impurities whatever the conditions used.

TABLE 1

| | | | | | C | Ta |
|---|---|---|---|---|---|---|
| | | | Time | Thickness | incorporation | incorporation |
| # | T (° C.) | P (Torr) | (min) | (nm) | (%) | (%) |
| 1 | 150 | 1 | 20 | 873 | — | — |
| 2 | 150 | 5 | 30 | 209 | — | — |
| 3 | 150 | 10 | 30 | 69 | 15 | 4.5 |
| 4 | 200 | 1 | 30 | 1050 | 21 | 10 |
| 5 | 200 | 5 | 30 | 357 | 9 | 2.5 |
| 6 | 200 | 10 | 30 | 267 | 8.5 | 2.0 |

### Example 2

### CVD Experiments with Metal Fluoride Precursors Synthesized “In Situ”

Deposition of MgF₂ was performed on native silicon oxide using Mg(MeCp)₂ as magnesium source and TaF₅ as fluorine source. Mg(MeCp)₂ was placed in a vessel heated at 45° C. and TaF₅ in a vessel at 60° C. Precursors were premixed in the gas phase at 60° C. before entering the deposition chamber. Typical CVD conditions were used at temperatures ranging from 150 to 250° C. and pressure ranging from 1 Torr (133 Pa) to 10 Torr (1333 Pa). Auger Electron Spectroscopy (AES) was used to assess atomic composition of the films. As seen in Table 1 the tantalum impurities are always below the detection limit of the Auger instrument.

TABLE 2

| | | | | | C | Ta |
|---|---|---|---|---|---|---|
| | | | Time | Thickness | incorporation | incorporation |
| # | T (° C.) | P (Torr) | (min) | (nm) | (%) | (%) |
| 1 | 150 | 1 | 60 | 27 | — | <0.2 |
| 2 | 150 | 5 | 30 | 28 | 8 | <0.2 |
| 3 | 150 | 10 | 30 | 29 | 9 | <0.2 |
| 4 | 200 | 1 | 30 | 15 | 4 | <0.2 |
| 5 | 200 | 5 | 30 | 56 | 5 | <0.2 |
| 6 | 200 | 10 | 30 | 110 | 6 | <0.2 |
| 7 | 250 | 1 | 30 | 59 | — | — |
| 8 | 250 | 5 | 30 | 113 | 3 | <0.2 |
| 9 | 250 | 10 | 15 | 85 | 4.5 | <0.2 |

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

We claim:

1. A method for depositing an alkaline earth metal fluoride film onto one or more substrates, comprising:
a) introducing a vapor of an alkaline earth metal precursor into a reaction chamber containing one or more substrates, the alkaline earth metal precursor having the general formula:
ML¹ₒₓY¹ₚ
wherein:
M is magnesium (Mg), calcium (Ca), strontium (Sr), or barium (Ba);
each L¹ is independently selected from the group consisting of acetylacetonate, enaminoketonate, β-diketiminate, diazabutadienyl, amidinate, formamidinate, guanidinate, iminomethylpyrrolyl, cyclopentadienyl, pentadienyl, cyclohexadienyl, hexadienyl, cycloheptadienyl, heptadienyl, cyclooctadienyl, and octadienyl, each of which may be substituted by C1-C4 linear, branched, or cyclic alkyl group; C1-C4 linear, branched, or cyclic mono, bis, or tris-alkylsilyl group; C1-C4 linear, branched, or cyclic alkylamino group; or a C1-C4 linear, branched, or cyclic fluoroalkyl group;
each Y¹ is a Lewis base independently selected from monoglyme, polyglyme, pyridine, THF, diethylether, or H₂O;
ox is an integer representing an oxidation state of the alkaline earth metal M; and
p is a number selected between 0 and 4;
b) introducing a vapor of at least one fluorinated metal precursor into the reaction chamber, the fluorinated metal precursor having the general formula:
NFₒₓₓ₋ₓL²_{oxx-y}Y²ₚ
wherein:
N is Titanium (Ti), Tantalum (Ta), Niobium (Nb), Xenon (Xe), Antimony (Sb), or Hafnium (Hf);
each L² is independently selected from the group consisting of acetylacetonate, enaminoketonate, β-diketiminate, diazabutadienyl, amidinate, formamidinate, guanidinate, iminomethylpyrrolyl, cyclopentadienyl, pentadienyl, cyclohexadienyl, hexadienyl, cycloheptadienyl, heptadienyl, cyclooctadienyl, and octadienyl, each of which may be substituted by C1-C4 linear, branched, or cyclic alkyl group; C1-C4 linear, branched, or cyclic mono, bis, or tris-alkylsilyl group; C1-C4 linear, branched, or cyclic alkylamino group; or a C1-C4 linear, branched, or cyclic fluoroalkyl group;
each Y² is a Lewis base independently selected from monoglyme, polyglyme, pyridine, THF, dimethylether, or diethyl ether;
oxx is an integer representing the oxidation state of the metal N;
x is an integer selected between 1 and oxx;
y is an integer selected between 0 and oxx;
the sum of x and y is equal to oxx;
p is a number selected between 0 and 4; and
the alkaline earth metal precursor is not Mg(tmhd)₂ when the fluorinated metal precursor is TiF₄ or TaF₅;
c) depositing the alkaline earth metal fluoride film onto the one or more substrates.

2. The method of claim 1, wherein the alkaline earth metal precursor is selected from the group consisting of MgCp₂, Mg(MeCp)₂, Mg(Cp*)₂, Mg(EtCp)₂, Mg(nPrCp)₂, Mg(iPrCp)₂, Mg(nBuCp)₂, Mg(isoBuCp)₂, Mg(secBuCp)₂, Mg(op)₂, Mg(acac)₂, Mg(acac)₂.2H₂O, Mg(acac)₂.tetraglyme, Mg(acac)₂.2H₂O.2diglyme, Mg(tmhd)₂, Mg(tmhd)₂.2H₂O, Mg(tmhd)₂.tetraglyme Mg(tmhd)₂.2H₂O.2diglyme, Mg(od)₂, Mg(tfac)₂, Mg(tfac)₂.2H₂O, Mg(tfac)₂.tetraglyme, Mg(tfac)₂.2H₂O.2diglyme, Mg(hfac)₂, Mg(hfac)₂.2H₂O, Mg(hfac)₂.tetraglyme, Mg(hfac)₂.2H₂O.2diglyme, Mg(mhd)₂, Mg(mhd)₂.2H₂O, Mg(mhd)₂.tetraglyme, Mg(mhd)₂.2H₂O.2diglyme, Mg(dibm)₂, Mg(tmod)₂, Mg(ibmp)₂, Mg(Et-diketiminate)₂, Mg(Et-ketoiminate)₂, Mg(di-iPr-amidinate)₂, Mg(di-tBu-amidinate)₂, Mg(di-iPr-formamidinate)₂, Mg(N,N′-Et₂-N″-Me₂-guanidinate)₂, Mg(N,N′-tBu₂-diazabutadienyl)₂, Mg(2-methyliminomethylpyrrolyl)₂, Mg(2-ethyliminomethylpyrrolyl)₂, Mg(2-isopropylimnomethylpyrrolyl)₂, and combinations thereof.

3. The method of claim 1, wherein the fluorinated metal precursor is selected from the group consisting of titanium tetrafluoride (TiF₄), titanium cyclopentadienyl trifluoride (TiCpF₃), titanium methylcyclopentadienyl trifluoride (TiMeCpF₃), titanium acetylacetonate trifluoride [Ti(acac)F₃], titanium 2,2,6,6-tetramethylhepta-3,5-dionate trifluoride [Ti(tmhd)F₃], titanium (amino)pent-3-en-2-one trifluoride [Ti(AcNac)F₃], titanium (methylamino)pent-3-en-2-one trifluoride [Ti(Me-AcNac)F₃], titanium (ethylamino)pent-3-en-2-one trifluoride [Ti(Et-AcNac)F₃], titanium (4N-aminopent-3-en-2N-iminato) trifluoride [Ti(NacNac)F₃], titanium (4N-ethylaminopent-3-en-2N-ethyliminato) trifluoride [Ti(Et-NacNac)F₃], titanium (diisopropylamidinato) trifluoride [Ti(iPrN═CMe-NiPr)F₃], titanium (diisopropylformamidinato) trifluoride [Ti(iPrN═CH—NiPr)F₃], titanium (diisopropylguanidinato) trifluoride [Ti(iPrN═C(NMe₂)-NiPr)F₃], titanium 2-methyliminomethylpyrrolyl trifluoride [Ti(2-MeN═CH—(C₄H₃N))F₃], titanium 2-ethyliminomethylpyrrolyl trifluoride [Ti(2-EtN═CH—(C₄H₃N))F₃], titanium 2-isopropyliminomethylpyrrolyl trifluoride [Ti(2-iPrN═CH—(C₄H₃N))F₃], tantalum pentafluoride (TaF₅), tantalum cyclopentadienyl tetrafluoride (TaCpF₄), tantalum methylcyclopentadienyl tetrafluoride (TaMeCpF₄), tantalum acetylacetonate tetrafluoride [Ta(acac)F₄], tantalum 2,2,6,6-tetramethylhepta-3,5-dionate tetrafluoride [Ta(tmhd)F₄], tantalum aminopent-3-en-2-one tetrafluoride [Ta(AcNac)F₄], tantalum methylaminopent-3-en-2-one tetrafluoride [Ta(Me-AcNac)F₄], tantalum ethylaminopent-3-en-2-one tetrafluoride [Ta(Et-AcNac)F₄], tantalum 4N-aminopent-3-en-2N-iminato tetrafluoride [Ta(NacNac)F₄], tantalum 4N-ethylaminopent-3-en-2N-ethyliminato tetrafluoride [Ta(Et-NacNac)F₄], tantalum diisopropylamidinato tetrafluoride [Ta(iPrN═CMe-NiPr)F₄)], tantalum diisopropylformamidinato tetrafluoride [Ta(iPrN═CH—NiPr)F₄], tantalum diisopropylguanidinato tetrafluoride [Ta(iPrN═C(NMe₂)-NiPr)F₄], tantalum 2-methyliminomethylpyrrolyl tetrafluoride [Ta(2-MeN═CH—(C₄H₃N))F₄], tantalum 2-ethyliminomethylpyrrolyl tetrafluoride [Ta(2-EtN═CH—(C₄H₃N))F₄], tantalum 2-isopropyliminomethylpyrrolyl tetra]fluoride [Ta(2-iPrN═CH—(C₄H₃N))F₄], tantalum biscyclopentadienyl trifluoride (TaCp₂F₃), tantalum bismethylcyclopentadienyl trifluoride [Ta(MeCp)₂F₃], tantalum bisacetylacetonate trifluoride [Ta(acac)₂F₃], tantalum bis 2,2,6,6-tetramethylhepta-3,5-dionate trifluoride [Ta(tmhd)₂F₃], tantalum bis(aminopent-3-en-2-one) trifluoride [Ta(AcNac)₂F₃], tantalum bis (methylaminopent-3-en-2-one) trifluoride [Ta(Me-AcNac)₂F₃], tantalum bis(ethylaminopent-3-en-2-one) trifluoride [Ta(Et-AcNac)₂F₃], tantalum bis(4N-aminopent-3-en-2N-iminato) trifluoride [Ta(NacNac)₂F₃], tantalum bis(4N-ethylaminopent-3-en-2N-ethyliminato) trifluoride [Ta(Et-NacNac)₂F₃], tantalum bis(diisopropylamidinato) trifluoride [Ta(iPrN═CMe-NiPr)F₃], tantalum bis(diisopropylformamidinato) trifluoride [Ta(iPrN═CH—NiPr)F₃], tantalum bis(diisopropylguanidinato) trifluoride [Ta(iPrN═C(NMe₂)-NiPr)F₃], tantalum bis(2-methyliminomethylpyrrolyl) trifluoride [Ta(2-MeN═CH—(C₄H₃N))F₃], tantalum bis(2-ethyliminomethylpyrrolyl) trifluoride [Ta(2-EtN═CH—(C₄H₃N))F₃], tantalum bis(2-isopropyliminomethylpyrrolyl) trifluoride [Ta(2-iPrN═CH—(C₄H₃N))F₃], niobium pentafluoride (NbF₅), niobium cyclopentadienyl tetrafluoride (NbCpF₄), niobium methylcyclopentadienyl tetrafluoride (NbMeCpF₄), niobium acetylacetonate tetrafluoride [Nb(acac)F₄], niobium 2,2,6,6-tetramethylhepta-3,5-dionate tetrafluoride [Nb(tmhd)F₄], niobium aminopent-3-en-2-one tetrafluoride [Nb(AcNac)F₄], niobium methylaminopent-3-en-2-one tetrafluoride [Nb(Me-AcNac)F₄], niobium ethylaminopent-3-en-2-one tetrafluoride [Nb(Et-AcNac)F₄], niobium 4N-aminopent-3-en-2N-iminato tetrafluoride [Nb(NacNac)F₄], niobium 4N-ethylaminopent-3-en-2N-ethyliminato tetrafluoride [Nb(Et-NacNac)F₄], niobium diisopropylamidinato tetrafluoride [Nb(iPrN═CMe-NiPr)F₄], niobium diisopropylformamidinato tetrafluoride [Nb(iPrN═CH—NiPr)F₄], niobium diisopropylguanidinato tetrafluoride [Nb(iPrN═C(NMe₂)-NiPr)F₄], niobium 2-methyliminomethylpyrrolyl tetrafluoride [Nb (2-MeN═CH—(C₄H₃N))F₄], niobium 2-ethyliminomethylpyrrolyl tetrafluoride [Nb (2-EtN═CH—(C₄H₃N))F₄], niobium 2-isopropyliminomethylpyrrolyl tetrafluoride [Nb (2-iPrN═CH—(C₄H₃N))F₄], niobium biscyclopentadienyl trifluoride (NbCp₂F₃), niobium bismethylcyclopentadienyl trifluoride [Nb(MeCp)₂F₃], niobium bisacetylacetonate trifluoride [Nb(acac)₂F₃], niobium bis(2,2,6,6-tetramethylhepta-3,5-dionate) trifluoride [Nb(tmhd)₂F₃], niobium bis(aminopent-3-en-2-one) trifluoride [Nb(AcNac)₂F₃], niobium bis(methylaminopent-3-en-2-one) trifluoride [N b(Me-AcNac)₂F₃], niobium bis(ethylaminopent-3-en-2-one) trifluoride [Nb(Et-AcNac)₂F₃], niobium bis(4N-aminopent-3-en-2N-iminato) trifluoride [Nb(NacNac)₂F₃], niobium bis(4N-ethylaminopent-3-en-2N-ethyliminato) trifluoride [Nb(Et-NacNac)₂F₃], niobium bis(diisopropylamidinato) trifluoride [Nb(iPrN═CMe-NiPr)F₃], niobium bis(diisopropylformamidinato) trifluoride [Nb(iPrN═CH—NiPr)F₃], niobium bis(diisopropylguanidinato) trifluoride [Nb(iPrN═C(NMe₂)-NiPr)F₃], niobium bis(2-methyliminomethylpyrrolyl) trifluoride [Nb (2-MeN═CH—(C₄H₃N))F₃], niobium bis(2-ethyliminomethylpyrrolyl) trifluoride [Nb (2-EtN═CH—(C₄H₃N))F₃], niobium bis(2-isopropyliminomethylpyrrolyl) trifluoride [Nb (2-iPrN═CH—(C₄H₃N))F₃], xenon difluoride (XeF₂), xenon cyclopentadienyl fluoride (XeCpF), xenon methylcyclopentadienyl fluoride (XeMeCpF), xenon acetylacetonate fluoride [Xe(acac)F], xenon 2,2,6,6-tetramethylhepta-3,5-dionate fluoride [Xe(tmhd)F], xenon aminopent-3-en-2-one fluoride [Xe(AcNac)F], xenon methylaminopent-3-en-2-one fluoride [Xe(Me-AcNac)F], xenon ethylaminopent-3-en-2-one fluoride [Xe(Et-AcNac)F], xenon 4N-aminopent-3-en-2N-iminato fluoride [Xe(NacNac)F], xenon 4N-ethylaminopent-3-en-2N-ethyliminato fluoride [Xe(Et-NacNac)F], xenon 2-methyliminomethylpyrrolyl fluoride [Xe (2-MeN═CH—(C₄H₃N))F], xenon 2-ethyliminomethylpyrrolyl fluoride [Xe (2-EtN═CH—(C₄H₃N))F], xenon 2-isopropyliminomethylpyrrolyl fluoride [Xe (2-iPrN═CH—(C₄H₃N))F], antimony pentafluoride (SbF₅), antimony cyclopentadienyl tetrafluoride (SbCpF₄), antimony methylcyclopentadienyl tetrafluoride (SbMeCpF₄), antimony acetylacetonate tetrafluoride [Sb(acac)F₄], antimony 2,2,6,6-tetramethylhepta-3,5-dionate tetrafluoride [Sb(tmhd)F₄], antimony (amino)pent-3-en-2-one tetrafluoride [Sb(AcNac)F₄], antimony (methylamino)pent-3-en-2-one tetrafluoride [Sb(Me-AcNac)F₄], antimony (ethylamino)pent-3-en-2-one tetrafluoride [Sb(Et-AcNac)F₄], antimony 4N-aminopent-3-en-2N-iminato tetrafluoride (Sb(NacNac)F₄), antimony 4N-ethylaminopent-3-en-2N-ethyliminato tetrafluoride (Sb(Et-NacNac)F₄), antimony diisopropylamidinato tetrafluoride (Sb(iPrN═CMe-NiPr)F₄), antimony diisopropylformamidinato tetrafluoride (Sb(iPrN═CH—NiPr)F₄), antimony diisopropylguanidinato tetrafluoride (Sb(iPrN═C(NMe₂)-NiPr)F₄), antimony 2-methyliminomethylpyrrolyl tetrafluoride (Sb (2-MeN═CH—(C₄H₃N))F₄), antimony 2-ethyliminomethylpyrrolyl tetrafluoride (Sb (2-EtN═CH—(C₄H₃N))F₄), antimony 2-isopropyliminomethylpyrrolyl tetrafluoride [Sb (2-iPrN═CH—(C₄H₃N))_{F}4], antimony bis(cyclopentadienyl)trifluoride (SbCp₂F₃), antimony bis(methylcyclopentadienyl)trifluoride (Sb (MeCp)₂F₃), antimony bis(acetylacetonate)trifluoride (Sb(acac)₂F₃), antimony bis(2,2,6,6-tetramethylhepta-3,5-dionate) trifluoride (Sb(tmhd)₂F₃), antimony bis(amino)pent-3-en-2-one) trifluoride (Sb(AcNac)₂F₃), antimony bis(methylamino)pent-3-en-2-one) trifluoride (Sb(Me-AcNac)₂F₃), antimony bis(ethylamino)pent-3-en-2-one) trifluoride (Sb(Et-AcNac)₂F₃), antimony bis(4N-aminopent-3-en-2N-iminato) trifluoride (Sb(NacNac)₂F₃), antimony bis(4N-ethylaminopent-3-en-2N-ethyliminato) trifluoride (Sb(Et-NacNac)₂F₃), antimony bis(diisopropylamidinato) trifluoride (Sb(iPrN═CMe-NiPr)₂F₃), antimony bis(diisopropylformamidinato) trifluoride (Sb(iPrN═CH—NiPr)₂F₃), antimony bis(diisopropylguanidinato) trifluoride (Sb(iPrN═C(NMe₂)-NiPr)₂F₃), antimony bis(2-methyliminomethylpyrrolyl) trifluoride (Sb(2-MeN═CH—(C₄H₃N))F₃), antimony bis(2-ethyliminomethylpyrrolyl) trifluoride (Sb(2-EtN═CH—(C₄H₃N))F₃), antimony bis(2-isopropyliminomethylpyrrolyl) trifluoride (Sb (2-iPrN═CH—(C₄H₃N))F₃), and hafnium tetrafluoride, preferably titanium tetrafluoride, tantalum pentafluoride, niobium pentafluoride, xenon difluoride, antimony pentafluoride, and hafnium tetrafluoride.

4. The method of claim 1, further comprising introducing the alkaline earth metal precursor and the fluorinated metal precursor into a pre-chamber prior to introducing them to the reaction chamber.

5. The method of claim 4, wherein the pre-chamber has a temperature below approximately 150° C.

6. The method of claim 1, wherein the alkaline earth metal fluoride film is deposited onto the one or more substrates by a chemical vapor deposition process or by an atomic layer deposition process.

7. The method of claim 6, wherein the chemical vapor deposition process or the atomic layer deposition process is plasma enhanced.

8. The method of claim 6, wherein the chemical vapor deposition process or the atomic layer deposition process is performed at a temperature below 250° C., preferably below 200° C.

9. The method of claim 6, wherein the chemical vapor deposition process or atomic layer deposition process is performed at a pressure between about 0.0001 Torr (0.013 Pa) and about 1000 Torr (13.33×10⁴ Pa), preferably between about 0.1 Torr (13.33 Pa) and about 300 Torr (40×10³ Pa).

10. The method of claim 1, further comprising introducing a reactant into the reaction chamber.

11. The method of claim 10, wherein the reactant is selected from the group consisting of F₂, NF₃, COF₂, BF₃, C₂F₆, C₂F₄, and C₃F₈.

12. The method of claim 10, wherein the reactant is selected from the group consisting of H₂, NH₃, SiH₄, Si₂H₆, Si₃H₈, O₂, O₃, H₂O, and H₂O₂.

13. The method of claim 1, further comprising introducing into the reaction chamber one or more elements.

14. The method of claim 13, wherein the one or more elements are oxygen, nitrogen, aluminum, or combinations thereof.

15. The method of claim 1, further comprising decreasing a refractive index of the alkaline earth metal fluoride film by a post treatment process.
